(19) United States
(12) Patent Application Publication
(10) Pub. No.: US 2022/0190284 A1
(43) Pub. Date: Jun. 16, 2022

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Sihang Bai, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/264,279

(22) PCT Filed: Jun. 19, 2020
(86) PCT No.: PCT/CN2020/097168

§ 371 Date: Jan. 28, 2021

(30) Foreign Application Priority Data
Jun. 11, 2020 (CN) 202010528744.6

(51) Int. Cl. H01L 51/52; H01L 51/56

(52) U.S. Cl. CPC H01L 51/5253; H01L 51/56

(57) ABSTRACT

A display panel and a manufacturing method thereof are provided. The method includes following steps: forming a transistor array layer in an opening area and a display area of the display panel, and forming a barrier layer and an encapsulation layer, which respectively covers the transistor array layer in the opening area and the transistor array layer in the display area.

### FIELD

The present disclosure relates to the field of display technologies, and more particularly, relates to a display panel and a manufacturing method thereof.

### BACKGROUND

Flexible organic light-emitting diodes (OLEDs) are convertible and foldable display devices. Compared with conventional rigid display panels, the flexible OLEDs have merits such as self-luminescence, wide viewing angles, high contrast, low power consumption, and extremely high response rates. With wide development and application of OLED technologies, display panels having improved viewing experience and high screen-to-body ratio (or even full screen) have become mainstream display technologies. For example, under-screen fingerprint recognition technologies, e.g., water-drop and O-cut designs, significantly increase a screen-to-body ratio of the display panels.

However, in conventional manufacturing processes of O-cut display panels, when layers in an opening area are formed, uneven coating and cracks may easily occur because the opening area cannot be fully covered by the layers due to a height difference between the opening area and a display area.

### SUMMARY

An embodiment of the present disclosure provides a display panel and a manufacturing method thereof to enhance thickness uniformity of layers in an opening area and a display area, thereby reducing a height difference between the opening area and the display area, and further preventing uneven coating and cracks from occurring on the opening area.

To solve the above technical problems, an embodiment of the present disclosure provides a manufacturing method of a display panel. The display panel includes an opening area and a non-opening area, and the non-opening area includes a gap area surrounding the non-opening area, and a display area surrounding the gap area. The display area and the opening area are separated from each other by the gap area.

The method includes:

S10, forming a transistor array layer on a substrate, and forming a first retaining wall and a second retaining wall, which correspond to the gap area and surround the opening area, on the substrate, wherein the transistor array layer includes a first array layer corresponding to the display area and a second array layer corresponding to the opening area, and the second retaining wall is disposed between the opening area and the first retaining wall;

S20, forming an encapsulation layer corresponding to the non-opening area, wherein the encapsulation layer at least covers the first array layer, and forming a barrier layer corresponding to the opening area and the gap area, wherein the barrier layer at least covers the second array layer;

S30, forming a touch control layer on the encapsulation layer and the barrier layer; and

S40, removing the substrate, the second array layer, the barrier layer, and the touch control layer, which correspond to the opening area, thereby forming a through-hole.

In one embodiment of the present disclosure, the step S10 further includes: forming one or more recesses, which correspond to the gap area and surround the opening area, on the substrate, wherein the one or more recesses are defined at least between the first retaining wall and the second retaining wall.

In one embodiment of the present disclosure, the encapsulation layer includes a first inorganic layer, an organic layer, and a second inorganic layer, which are stacked, the first inorganic layer and the second inorganic layer continuously cover the first array layer and the first retaining wall and are blocked by the second retaining wall, and the organic layer covers the first array layer and is blocked by the first retaining wall.

In one embodiment of the present disclosure, the first inorganic layer and the second inorganic layer cover an inner wall of the one or more recesses.

In one embodiment of the present disclosure, the barrier layer continuously at least covers the second array layer, the second retaining wall, and the first inorganic layer and the second inorganic layer corresponding to the barrier layer, and the barrier layer is filled in all or part of one or more of the recesses.

In one embodiment of the present disclosure, the substrate includes a substrate layer and a buffer layer disposed on the substrate layer, and the one or more recesses penetrate the buffer layer and part of the substrate layer.

In one embodiment of the present disclosure, in the step S20, an upper surface of the barrier layer corresponding to the opening area is aligned with an upper surface of the encapsulation layer corresponding to the display area.

In one embodiment of the present disclosure, the barrier layer includes a photoresist material.

To achieve the above goal, the present disclosure provides a display panel, including an opening area and a non-opening area, wherein the non-opening area includes a gap area surrounding the opening area and a display area surrounding the gap area, and the display area and the opening area are separated from each other by the gap area; and

the display panel further includes:

a substrate;

a first array layer corresponding to the display area and disposed on the substrate;

a first retaining wall and a second retaining wall, which are disposed on the substrate and surround the opening area, wherein the second retaining wall is disposed between the opening area and the first retaining wall;

an encapsulation layer corresponding to the non-opening area, wherein the encapsulation layer at least covers the first array layer;

a barrier layer corresponding to the opening area and the gap area, wherein the barrier layer at least covers the encapsulation layer corresponding to the gap area; and

a touch control layer disposed on the encapsulation layer and the barrier layer;

wherein the opening area is provided with a through-hole, and the through-hole penetrates the substrate, the barrier layer, and the touch control layer corresponding to the opening area.

In one embodiment of the present disclosure, the gap area includes one or more recesses, which correspond to the opening area, on the substrate, and the one or more recesses are defined at least between the first retaining wall and the second retaining wall.

In one embodiment of the present disclosure, the encapsulation layer includes a first inorganic layer, an organic layer, and a second inorganic layer, which are stacked, the first inorganic layer and the second inorganic layer continuously cover the first array layer and the first retaining wall and are blocked by the second retaining wall, and the organic layer covers the first array layer and is blocked by the first retaining wall.

In one embodiment of the present disclosure, the first inorganic layer and the second inorganic layer cover an inner wall of the one or more recesses.

In one embodiment of the present disclosure, the barrier layer continuously at least covers the second array layer, the second retaining wall, and the first inorganic layer and the second inorganic layer corresponding to the barrier layer, and the barrier layer is filled in all or part of one or more of the recesses.

In one embodiment of the present disclosure, the substrate includes a substrate layer and a buffer layer disposed on the substrate layer, and the one or more recesses penetrate the buffer layer and part of the substrate layer.

In one embodiment of the present disclosure, in the step S20, an upper surface of the barrier layer corresponding to the opening area is aligned with an upper surface of the encapsulation layer corresponding to the display area.

In one embodiment of the present disclosure, the barrier layer includes a photoresist material.

Regarding the beneficial effects: compared with conventional technologies, in the present disclosure, a transistor array layer is disposed both in a display area and an opening area, and a barrier layer is disposed in the opening area, thereby improving thickness uniformity of layers in the opening area and the display area. Thus, a height difference between the opening area and the display area is reduced, layers can be well filled in the opening area, cracks and uneven thickness of the layers in the opening area can be prevented, and a product yield rate can be improved. Furthermore, in a manufacturing method of the display panel provided by the present disclosure, it is not necessary to add additional mask plates and processes, thereby saving manufacturing costs and manufacturing periods.

### DESCRIPTION OF DRAWINGS

Technical solutions and beneficial effects of the present disclosure are illustrated below in detail in conjunction with drawings and specific embodiments.

FIG. 1 is a flowchart showing a manufacturing method of a display panel provided by an embodiment of the present disclosure.

FIG. 2 is a structural schematic view showing the display panel manufactured by the manufacturing method provided by the embodiment of the present disclosure.

FIG. 3 is a structural schematic view showing the display panel manufactured by the manufacturing method provided by the embodiment of the present disclosure.

FIG. 4 is a structural schematic view showing the display panel manufactured by the manufacturing method provided by the embodiment of the present disclosure.

FIG. 5 is a structural schematic view showing the display panel manufactured by the manufacturing method provided by the embodiment of the present disclosure.

FIG. 6 is a structural schematic view showing the display panel manufactured by the manufacturing method provided by the embodiment of the present disclosure.

FIG. 7 is a plan structural schematic view showing distribution of areas on the display panel.

### DETAILED DESCRIPTION

Hereinafter preferred embodiments of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or significance. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The disclosure below provides many different embodiments or examples for realizing different structures of the present disclosure. In order to simplify the disclosure of the present disclosure, components and settings of specific examples are described below. Of course, they are only examples and are not intended to limit the present disclosure. Furthermore, reference numbers and/or letters may be repeated in different examples of the present disclosure. Such repetitions are for simplification and clearness, which per se do not indicate the relations of the discussed embodiments and/or settings. Moreover, the present disclosure provides examples of various specific processes and materials, but the applicability of other processes and/or application of other materials may be appreciated by a person skilled in the art.

An embodiment of the present disclosure provides a display panel to solve a following conventional technical problem: due to a relatively great height difference between an opening area and a display area, sequential manufacturing processes of layers are affected. Also, cracks and uneven coating may occur on layers in the opening area because the opening area cannot be fully covered by the layers, which affects display effect and a yield rate of products.

To solve the above technical problems, an embodiment of the present disclosure provides a manufacturing method of a display panel. The display panel includes an opening area 111 and a non-opening area 112, and the non-opening area 112 includes a gap area 1121 surrounding the opening area 111, and a display area 1122 surrounding the gap area 1121. The display area 1122 and the opening area 111 are separated from each other by the gap area 1121.

The method includes:

S10, forming a transistor array layer 102 on a substrate 101, and forming a first retaining wall 1031 and a second retaining wall 1032, which correspond to the gap area 1121 and surround the opening area 111, on the substrate 101, wherein the transistor array layer 102 includes a first array layer 1021 corresponding to the display area 1122 and a second array layer 1022 corresponding to the opening area 111, and the second retaining wall 1032 is disposed between the opening area 111 and the first retaining wall 1031;

S20, forming an encapsulation layer 105 corresponding to the non-opening area 112, wherein the encapsulation layer 105 at least covers the first array layer 1021, and forming a barrier layer 106 corresponding to the opening area 111 and the gap area 1121, wherein the barrier layer 106 at least covers the second array layer 1022;

S30, forming a touch control layer 107 on the encapsulation layer 105 and the barrier layer 106; and

S40, removing the substrate 101, the second array layer 1022, the barrier layer 106, and the touch control layer 107, which correspond to the opening area 111, thereby forming a through-hole 113.

In conventional manufacturing processes of display panels, due to a relatively great height difference between an opening area and a display area, sequential manufacturing processes of layers are affected. Therefore, cracks and uneven coating may occur on layers in the opening area because the opening area cannot be fully covered by the layers, which affects display effect and a yield rate of products. In the present disclosure, a transistor array layer is disposed both in a display area and an opening area, and a barrier layer is disposed in the opening area, thereby improving thickness uniformity of layers in the opening area and the display area. Thus, a height difference between the opening area and the display area is reduced, layers can be well filled in the opening area, cracks and uneven thickness of the layers in the opening area can be prevented, and a product yield rate can be improved. Furthermore, in a manufacturing method of the display panel provided by the present disclosure, it is not necessary to add additional mask plates and processes, thereby saving manufacturing costs and manufacturing periods.

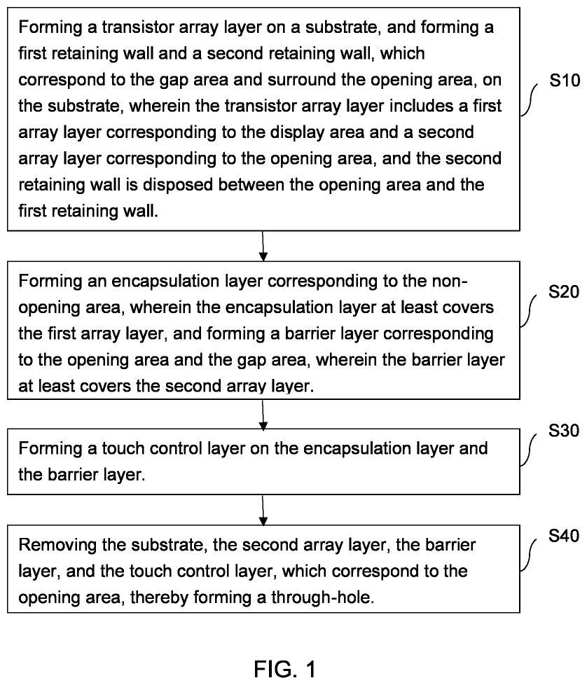

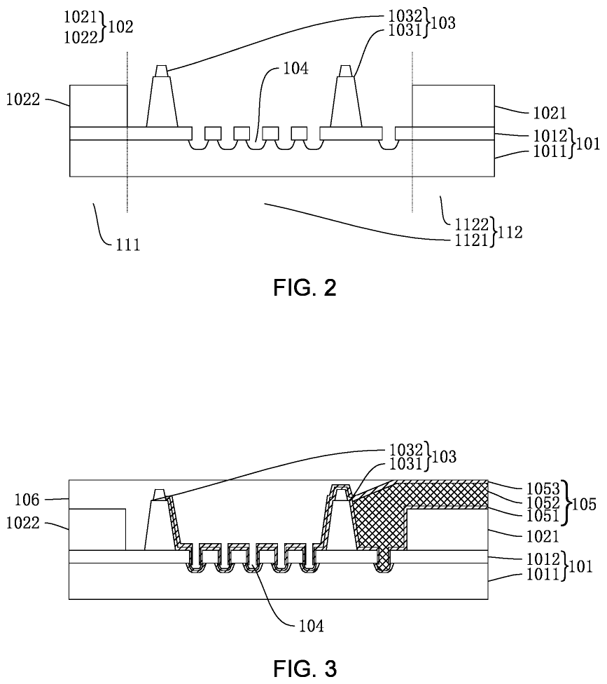

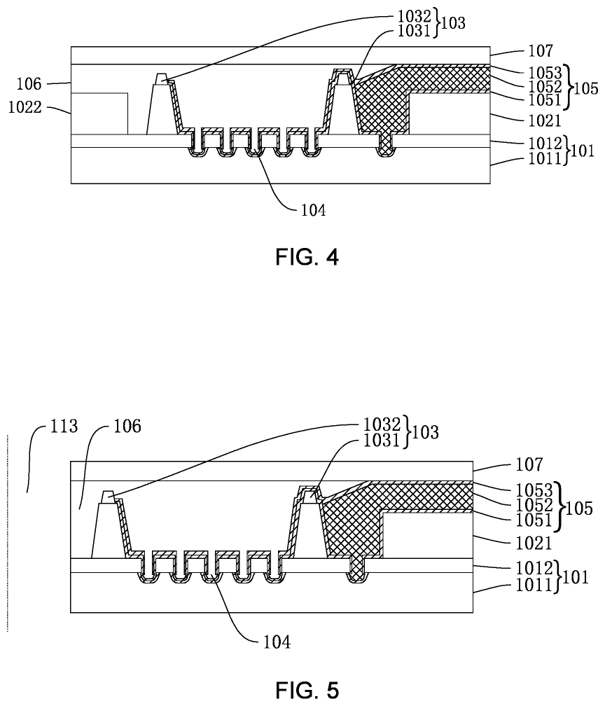

Specifically, please refer to FIGS. 1 to 7, the manufacturing method of the display panel provided by the present embodiment is described in detail below. The display panel includes the opening area 111 and the non-opening area 112. The non-opening area 112 includes the gap area 1121 surrounding the opening area 111 and the display area 1122 surrounding the gap area 1121. The display area 1122 and the opening area 111 are separated from each other by the gap area 1121.

Furthermore, the method includes:

S10, forming the transistor array layer 102 on the substrate 101, and forming the first retaining wall 1031 and the second retaining wall 1032, which correspond to the gap area 1121 and surround the opening area 111, on the substrate 101, wherein the transistor array layer 102 includes the first array layer 1021 corresponding to the display area 1122 and the second array layer 1022 corresponding to the opening area 111, and the second retaining wall 1032 is disposed between the opening area 111 and the first retaining wall 1031.

The substrate 101 is provided and includes a substrate layer 1011 and a buffer layer 1012 disposed on the substrate layer 1011. A material of the substrate layer 1011 includes polyimide, but is not limited thereto. Furthermore, the substrate layer 1011 is not limited to a single-layer substrate or a multi-layer substrate, and may be determined according to an actual situation.

The transistor array layer 102 is disposed on the substrate 11. The transistor array layer 102 includes a first array layer 1021 corresponding to the display area 1122 and a second array layer 1022 corresponding to the opening area 111. Specifically, the transistor array layer 102 includes a gap layer disposed on the substrate 101, a transistor device covered in the gap layer, a planarization layer and a pixel defining layer disposed on the barrier layer, and a luminescent layer disposed on the pixel defining layer. The above layer may be manufactured according to conventional manufacturing processes, which are not described here.

In addition, the first retaining wall 1031 and the second retaining wall 1032, which correspond to the gap area 1121 and surround the opening area 111, are disposed on the substrate 101. The second retaining wall 1032 is disposed between the first retaining wall 1031 and the opening area 111, the second retaining wall 1032 is disposed on a side of the gap area 1121 near the opening area 111, and the first retaining wall 1031 is disposed on a side of the gap area 1121 near the display area 1122. A retaining wall structure 103 formed from the first retaining wall 1031 and the second retaining wall 1032, the planarization layer, and the pixel defining layer may be simultaneously formed. Specifically, a layer structure with a certain thickness may be formed on a corresponding area of the gap area 1121 when the planarization layer and the pixel defining layer are formed, thereby forming the retaining structure 103. Furthermore, a photoresist material may be disposed on the retaining wall structure according to actual situations, thereby increasing a height of the retaining wall structure 103, and satisfying actual requirements.

In the present embodiment, one or more recesses 104, which correspond to the gap area 1121 and surround the opening area 111, are defined on the substrate 101, and the one or more recesses 104 are defined at least between the first retaining wall 1031 and the second retaining wall 1032. In the present embodiment, the plurality of recesses 104 are provided and may be disposed at two sides of the first retaining wall 1031.

The one or more recesses 104 penetrate the buffer layer 1012 and part of the substrate layer 1011. After an opening is defined on the opening area 111, the recesses 104 may block moisture in the substrate 101 from entering a channel, thereby protecting a display device of the display panel.

S20, forming an encapsulation layer 105 corresponding to the non-opening area 112, wherein the encapsulation layer 105 at least covers the first array layer 1021, and forming a barrier layer 106 corresponding to the opening area 111 and the gap area 1121, wherein the barrier layer 106 at least covers the second array layer 1022.

The encapsulation layer 105 and the barrier layer 106 are disposed on the transistor array layer 102. The encapsulation layer 105 corresponds to the non-opening area and at least covers the first array layer 1021. The barrier layer 106 corresponds to the opening area 111 and the gap area 1121 and at least covers the second array layer 1022.

Specifically, the encapsulation layer 105 includes a first inorganic layer 1051, an organic layer 1052, and a second inorganic layer 1053. The first inorganic layer 1051 and the second inorganic layer 1053 cover the first array layer 1021 and the first retaining wall 1031, and are blocked by the second retaining wall 1032. The first inorganic layer 1051 and the second inorganic layer 1053 are blocked at a side of the second retaining wall 1032 toward the display area 1122, and may fully or partly cover the side wall of the second retaining wall 1032 toward the display area 1122. The organic layer 1052 covers the first array layer 1021, is blocked by the first retaining wall 1031, and is filled in the recesses 104 near the side wall of the second retaining wall 1032 toward the display area 1122. The organic layer 1052 is blocked by a side of the first retaining wall 1031 toward the display area 1122 and partly covers the side wall of the first retaining wall 1031 toward the display area 1122. Therefore, the organic layer 1052 is blocked by the first retaining wall 1031, the organic layer 1031 may be prevented from leakage during an inkjet printing process, and encapsulation effect of the display panel may be ensured. Moreover, since the second retaining wall 1032 is provided in a direction from the side of the first retaining wall 1031 away from the display area 1122, the encapsulation effect is further enhanced.

The first inorganic layer 1051 and the second inorganic layer 1053 further cover an inner wall of the one or more recesses 104. The one or more recesses 104 may block moisture in the substrate 101 from entering the channel, thereby enhancing the encapsulation effect of the display panel.

In the present embodiment, the barrier layer 106 covers the second array layer 1022, the second retaining wall 1032, and the encapsulation layer 105 corresponding to the gap area 1121. Specifically, the encapsulation layer 105 includes the first inorganic layer 1051 and the second inorganic layer 1052. The barrier layer 106 is partly or fully filled in the one or more recesses 104. In the present embodiment, the barrier layer 106 only covers the one or more recesses 104 between the first retaining wall 1031 and the second retaining wall 1032, thereby improving adhesion between the barrier layer 106 and the substrate 101, and enhancing stability of the display panel.

In the present embodiment, an upper surface of the barrier layer 106 corresponding to the opening area 111 is aligned with an upper surface of the encapsulation layer 105 corresponding to the display area 1122. Furthermore, the barrier layer 106 may cover the first retaining wall 1031, and may be filled in a height difference between the first retaining wall 1031 and the encapsulation layer 105, thereby improving flatness of layers. As a result, a height difference may be prevented from occurring between the opening area 111 and the display area 1122, and cracks of layers caused by uneven coating or incomplete coating may be prevented during sequential manufacturing processes of layer structures.

Preferably, the barrier layer 106 includes a photoresist material, and is not limited to a light-transmitting photoresist material or an opaque photoresist material.

S30, forming a touch control layer 107 on the encapsulation layer 105 and the barrier layer 106.

The touch control layer 107 is disposed on the encapsulation layer 105 and the barrier layer 106. Because the encapsulation layer 105 and the barrier layer 106 form a flat layer, a thickness of the touch control layer 107 may be uniform. Furthermore, the touch control layer 107 may include a mutual capacitance structure and may be manufactured according to conventional processes which are not described here.

S40, removing the substrate 101, the second array layer 1022, the barrier layer 106, and the touch control layer 107, which correspond to the opening area 111, thereby forming a through-hole 113.

A cutting process is performed on the opening area 111 to form an opening. In the cutting process, the substrate 101, the second array layer 1022, the barrier layer 106, and the touch control layer 107 in the opening area 111 are removed, thereby forming the through-hole 113.

Furthermore, a polarizer 108 and a cover plate 110 must be sequentially formed on the touch control layer 107, wherein the cover plate 110 is attached to the display panel by an optically clear adhesive 109.

In summary, the embodiment of the present disclosure provides the manufacturing method of the display panel. By disposing the same transistor array layer on the opening area and the display area, a height difference between the opening area and the display area may be reduced. Therefore, layers can be well filled in the opening area, cracks of layers caused by uneven coating or incomplete coating may be prevented during processes, and thicknesses of layers formed in sequentially processes may be uniform. As a result, a yield rate and display effect of the display panel can be improved. Moreover, in the present embodiment, some layers corresponding to the opening area are removed, thereby effectively improving light transmittance of the opening area of the display panel. Furthermore, in the method provided by the present embodiment, a flat, uniform, and complete structure can be obtained without adding additional mask plates. Thus, manufacturing costs and manufacturing processes are reduced.

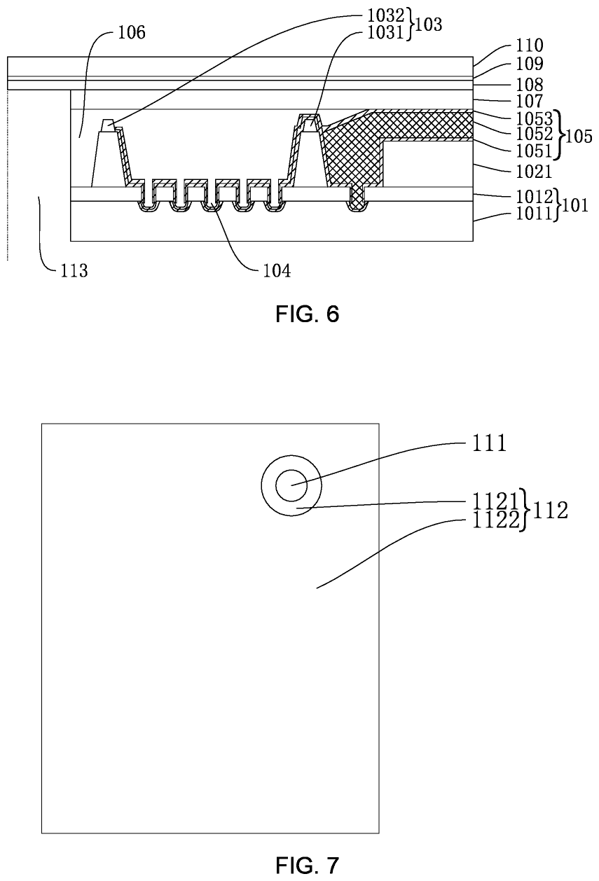

In addition, an embodiment of the present disclosure provides a display panel formed according to the above-mentioned method. As shown in FIG. 6 and FIG. 7, the display panel includes an opening area 111 and a non-opening area 112, and the non-opening area 112 includes a gap area 1121 surrounding the non-opening area, and a display area 1122 surrounding the gap area. The display area 1122 and the opening area 111 are separated from each other by the gap area 1121.

Specifically, the display panel further includes: a substrate 101; an array layer 1021 corresponding to the display area 1122 and disposed on the substrate 101; a first retaining wall 1031 and a second retaining wall 1032, which correspond to a gap area 1121, disposed on the substrate 101 and surrounding the opening area 111, wherein the second retaining wall 1032 is disposed between the opening area 111 and the first retaining wall 1031; an encapsulation layer 105 corresponding to the non-opening area 112 and at least covering the first array layer 1021; a barrier layer 106 corresponding to the opening area 111 and the gap area 1121 and at least covering the encapsulation layer 105 corresponding to the gap area 1121; a touch control layer 107 disposed on the encapsulation layer 105 and the barrier layer 106, wherein a through-hole 113 is defined in the opening area 111 and penetrates the substrate 101, the barrier layer 106, and the touch control layer 107 in the opening area 111.

The gap area 1121 includes one or more recesses 104 surrounding the opening area 111 and disposed on the substrate 101, and the one or more recesses 104 are defined at least between the first retaining wall 1031 and the second retaining wall 1032. Furthermore, the encapsulation layer 105 covers an inner wall of the one or more recesses 104, thereby blocking moisture in the substrate 101 from entering a channel. Therefore, an encapsulation effect of the display panel can be improved.

The substrate 101 includes a substrate layer 1011 and a buffer layer 1012, which are disposed on the substrate layer 1011, and the recesses 104 penetrate the buffer layer 1012 and part of the substrate layer 1011.

Furthermore, a polarizer 108 and a cover plate 110 are sequentially formed on the touch control layer 107, wherein the cover plate 110 is attached to the display panel by an optically clear adhesive 109.

In summary, in the display panel provided by the present embodiment, the encapsulation layer and the barrier layer are uniform and flat. Therefore, thicknesses of layers formed in sequential processes can be even, and display effect and a yield rate can be improved. Moreover, in the present embodiment, the through-hole penetrates the transistor array layer, the barrier layer, and the touch control layer, which significantly improves light transmittance of the display panel. As a result, images can be clearly displayed by an under-screen device.

In the above embodiments, the focus of each embodiment is different, and for a part that is not detailed in an embodiment, reference may be made to related descriptions of other embodiments.

A display panel and a manufacturing method thereof have been described in detail with embodiments provided by the present disclosure which illustrates principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A method of manufacturing a display panel, wherein the display panel comprises an opening area and a non-opening area, the non-opening area includes a gap area surrounding the opening area and a display area surrounding the gap area, and the display area and the opening area are separated from each other by the gap area; and
the method comprises following steps:
S10, forming a transistor array layer on a substrate, and forming a first retaining wall and a second retaining wall, which correspond to the gap area and surround the opening area, on the substrate, wherein the transistor array layer comprises a first array layer corresponding to the display area and a second array layer corresponding to the opening area, and the second retaining wall is disposed between the opening area and the first retaining wall;
S20, forming an encapsulation layer corresponding to the non-opening area, wherein the encapsulation layer at least covers the first array layer, and forming a barrier layer corresponding to the opening area and the gap area, wherein the barrier layer at least covers the second array layer;
S30, forming a touch control layer on the encapsulation layer and the barrier layer; and
S40, removing the substrate, the second array layer, the barrier layer, and the touch control layer, which correspond to the opening area, thereby forming a through-hole.

2. The method of claim 1, wherein the step S10 further comprises a following step: forming one or more recesses, which correspond to the gap area and surround the opening area, on the substrate, wherein the one or more recesses are defined at least between the first retaining wall and the second retaining wall.

3. The method of claim 2, wherein the encapsulation layer comprises a first inorganic layer, an organic layer, and a second inorganic layer, which are stacked, the first inorganic layer and the second inorganic layer cover the first array layer and the first retaining wall and are blocked by the second retaining wall, and the organic layer covers the first array layer and is blocked by the first retaining wall.

4. The method of claim 3, wherein the first inorganic layer and the second inorganic layer cover an inner wall of the one or more recesses.

5. The method of claim 4, wherein the barrier layer at least covers the second array layer, the second retaining wall, and the first inorganic layer and the second inorganic layer corresponding to the gap area, and the barrier layer is filled in all or part of the one or more of recesses.

6. The method of claim 2, wherein the substrate comprises a substrate layer and a buffer layer disposed on the substrate layer, and the one or more recesses penetrate the buffer layer and part of the substrate layer.

7. The method of claim 1, wherein in the step S20, an upper surface of the barrier layer corresponding to the opening area is aligned with an upper surface of the encapsulation layer corresponding to the display area.

8. The method of claim 1, wherein the barrier layer comprises a photoresist material.

9. A display panel, comprising an opening area and a non-opening area, wherein the non-opening area includes a gap area surrounding the opening area and a display area surrounding the gap area, and the display area and the opening area are separated from each other by the gap area; and
the display panel further comprises:
a substrate;
a first array layer corresponding to the display area and disposed on the substrate;
a first retaining wall and a second retaining wall, which are disposed on the substrate and surround the opening area, wherein the second retaining wall is disposed between the opening area and the first retaining wall;
an encapsulation layer corresponding to the non-opening area, wherein the encapsulation layer at least covers the first array layer;
a barrier layer corresponding to the opening area and the gap area, wherein the barrier layer at least covers the encapsulation layer corresponding to the gap area; and
a touch control layer disposed on the encapsulation layer and the barrier layer;
wherein the opening area is provided with a through-hole, and the through-hole penetrates the substrate, the barrier layer, and the touch control layer corresponding to the opening area.

10. The display panel of claim 9, wherein the gap area comprises one or more recesses, which correspond to the opening area, on the substrate, and the one or more recesses are defined at least between the first retaining wall and the second retaining wall.

11. The display panel of claim 10, wherein the encapsulation layer comprises a first inorganic layer, an organic layer, and a second inorganic layer, which are stacked, the first inorganic layer and the second inorganic layer cover the first array layer and the first retaining wall and are blocked by the second retaining wall, and the organic layer covers the first array layer and is blocked by the first retaining wall.

12. The display panel of claim 11, wherein the first inorganic layer and the second inorganic layer cover an inner wall of the one or more recesses.

13. The display panel of claim 12, wherein the barrier layer at least covers the second array layer, the second retaining wall, and the first inorganic layer and the second inorganic layer corresponding to the barrier layer, and the barrier layer is filled in all or part of one or more of the recesses.

14. The display panel of claim 10, wherein the substrate comprises a substrate layer and a buffer layer disposed on the substrate layer, and the one or more recesses penetrate the buffer layer and part of the substrate layer.

15. The display panel of claim 9, wherein an upper surface of the barrier layer corresponding to the opening area is aligned with an upper surface of the encapsulation layer corresponding to the display area.

16. The display panel of claim 9, wherein the barrier layer comprises a photoresist material.
